(19) United States
(12) Patent Application Publication
(10) Pub. No.: US 2026/0302133 A1
(43) Pub. Date: Oct. 1, 2026

(54) CASCADE ARC PLASMA GENERATOR

(71) Applicant: Hefei Institute of Physical Science, Chinese Academy of Sciences, Hefei, Anhui (CN)

(72) Inventors: Haishan Zhou, Hefei, Anhui (CN); Weiyun Zhou, Hefei, Anhui (CN); Xin Yang, Hefei, Anhui (CN); Yu Li, Hefei, Anhui (CN); Guangnan Luo, Hefei, Anhui (CN)

(21) Appl. No.: 19/209,882

(22) Filed: May 16, 2025

(30) Foreign Application Priority Data
Sep. 6, 2024 (CN) 202411245956.8

(51) Int. Cl. H01J 37/32; H01J 37/02

(52) U.S. Cl. CPC H01J 37/32055; H01J 37/02; H01J 2237/002

(57) ABSTRACT

A cascade arc plasma generator including a cathode structure, a cascade structure, and an anode structure sequentially connected. When the cascade arc plasma generator works, working gas enters an ionization chamber through a gas inlet channel, a potential difference exists between arc starting pins and an anode body, and the working gas is ionized to form a plasma, which is jetted outside the cascade arc plasma generator through the ionization chamber, a plasma channel, and an anode channel that are connected in sequence, and enters an external device to interact with a material sample. The arc starting pins are parallel to each other and arranged at intervals, and ends of tips thereof are located in a same plane to form a planar plasma source being able to irradiate a large-area material sample or a plurality of material samples at a time.

### CROSS REFERENCE TO RELATED APPLICATIONS

The present application claims the benefit of Chinese Patent Application No. 202411245956.8 filed on Sep. 6, 2024, the contents of which are incorporated herein by reference in their entirety.

### TECHNICAL FIELD

The present disclosure relates to the field of plasma, and in particular to a cascade arc plasma generator.

### BACKGROUND

Controlled nuclear fusion has the advantages of safety, cleanliness, abundant fuel, and the like, and is one of main options for solving future energy problems. At present, two common methods to realize controlled nuclear fusion are magnetic confinement fusion and inertial confinement fusion; the principle of the inertial confinement fusion is simple, which is to use a huge pressure generated by laser to make a volume of nuclear fuel decrease and a density of the nuclear fuel increase in a very short time, and atomic nucleus undergoes a fusion reaction to release energy; and the principle of the magnetic confinement fusion is to use a magnetic field to confine the nuclear fuel of the plasma with extremely high temperature, to make it to react.

However, in a magnetic confinement fusion device, there is a strong interaction between a strong heat flow and a strong particle flow from the high-temperature plasma and a wall directly facing the plasma, which will not only lead to a damage of the first wall, causing a loss of plasma energy radiation and plasma confinement performance to be reduced, but will also directly affect a plasma density control; therefore, it is necessary to study a mechanism of the interaction between the plasma and a wall material, with an aim of developing materials capable of withstanding a plasma environment; the materials usually need to have characteristics of high heat resistance, irradiation stability, chemical inertness and the like, to ensure a safety and a stable operation of a nuclear fusion reactor.

In the study of the mechanism of the interaction between the nuclear fusion reactor plasma and the material, it is necessary to provide the plasma environment; at present, experiments usually use a plasma generator to provide a plasma environment, and among a variety of plasma generators, plasma generated by a cascade arc plasma generator has a high energy density, which is more suitable for the study of the mechanism of the interaction between nuclear fusion reactor plasma and material.

In the prior art, a cascade arc plasma generator is usually a cascade arc plasma generator with one cathode or a cascade arc plasma generator with three cathodes, the cascade arc plasma generator with one cathode includes one cathode provided with an arc starting pin, and the cascade arc plasma generator with three cathodes includes three cathodes provided with three arc starting pins respectively, and tips of the three arc starting pins are intersected at one position. Whether it is one cathode or three cathodes, the plasma generated is a point source due to an arc starting principle and structure, and it is not possible to irradiate a plurality of material samples or a large-area material sample at a time in a study of plasma-material interaction in nuclear fusion reactors, which greatly affects an efficiency of the irradiation, and raises a cost of a single test study.

### SUMMARY

An object of the present disclosure is to provide a cascade arc plasma generator, to solve a problem that an existing cascade arc plasma generator is unable to irradiate a plurality of material samples or irradiate a large-area material sample at a time.

In order to achieve the above object, the present disclosure provides a cascade arc plasma generator, including a cathode structure, a cascade structure, and an anode structure sequentially connected along a plasma jet direction.

The cathode structure includes a cathode assembly and a cathode seat, the cathode assembly includes an arc starting pin seat and a plurality of arc starting pins, and the plurality of the arc starting pins are parallel to each other and are connected to one end of the arc starting pin seat at intervals; the cathode seat is provided with an ionization chamber, the ionization chamber runs through the cathode seat in the plasma jet direction, and the arc starting pin seat is partially disposed in the ionization chamber so that the plurality of the arc starting pins are located in the ionization chamber, ends of tips of the plurality of the arc starting pins are disposed towards the cascade structure, the ends of the tips of the plurality of the arc starting pins are located in a same plane, and the plane is perpendicular to the plasma jet direction; the cathode seat is further provided with a plurality of gas inlet channels, and the gas inlet channels are configured to deliver gases into the ionization chamber.

The anode structure includes an anode body, the anode body is provided with an anode channel running through an upper surface and a lower surface of the anode body.

The cascade structure includes a plurality of cascade pieces, the plurality of the cascade pieces are sequentially stacked along the plasma jet direction and disposed between the cathode seat and the anode body; each of the cascade pieces is provided with a cascade channel, the cascade channel runs through the cascade piece in the plasma jet direction, so that when the plurality of the cascade pieces are stacked, a plurality of the cascade channels are sequentially communicated to form a plasma channel; and the ionization chamber, the plasma channel, and the anode channel are provided opposite to each other and sequentially communicated.

Further, a first protrusion is provided at an end, facing the cascade structure, of the arc starting pin seat, the first protrusion is embedded in the ionization chamber, and the arc starting pins are provided on an end surface of the first protrusion.

Further, the cathode structure further includes a water-cooling assembly.

A first mounting cavity is provided at one end, away from the arc starting pins, of the arc starting pin seat, the water-cooling assembly is hermetically connected to the first mounting cavity.

Further, the water-cooling assembly includes a water-cooling box, a water inlet pipe, and a water outlet pipe.

The water-cooling box is hermetically connected to the first mounting cavity, a gap is formed between a bottom surface of the water-cooling box and a bottom surface of the first mounting cavity, and a cooling channel is formed by an enclosure of an outer wall of the water-cooling box and a cavity wall of the first mounting cavity. The water-cooling box is provided therein with a water inlet channel and a water outlet channel, both of which run through two side surfaces of the water-cooling box, and the two side surfaces are in the plasma jet direction, and the water inlet channel and the water outlet channel are communicated with the cooling channel respectively.

The water inlet pipe is communication with the water inlet channel, and the water outlet pipe is communication with the water outlet channel.

Further, the cathode structure further includes a protection ring, the protection ring is disposed in the ionization chamber and is hermetically connected to an inner side wall of the ionization chamber; the protection ring includes a sleeving portion and a jet portion sequentially disposed along the plasma jet direction, the sleeving portion is provided with a sleeving channel, the jet portion is provided with a jet channel, and the sleeving channel is communicated with the jet channel.

The sleeving portion sleeves outside the first protrusion, an inner surface of the sleeving portion is tightly attached to an outer surface of the first protrusion, and an outer surface of the sleeving portion is tightly attached to a cavity wall of the ionization chamber.

The jet portion is provided outside the ends of the tips of the plurality of the arc starting pins, a gap exists between an inner surface of the jet portion and each of the arc starting pins, an outer surface of the jet portion is tightly attached to the cavity wall of the ionization chamber, and a diameter of the jet channel gradually decreases from top to bottom.

Further, the cascade arc plasma generator further includes a connecting structure, the connecting structure includes a flange, a plurality of connecting rods, and a plurality of groups of locking nuts, and a number of the groups of the locking nuts is the same as a number of the connecting rods.

The flange covers and is provided above the end, away from the arc starting pins, of the arc starting pin seat, and the flange is further provided with first connecting holes with a number thereof same as the connecting rods. Each of the connecting rods is arranged along the plasma jet direction, and is provided with one end fixedly arranged on the anode body, and an other end passing through one of the first connecting holes and fixedly connected with one group of the locking nuts, and the connecting rods are made of insulating materials.

Further, the cascade structure further includes a plurality of first gaskets and a second gasket, each of the plurality of first gaskets is provided between two adjacent cascade pieces.

The second gasket is provided between the cathode seat and an uppermost cascade piece of the cascade structure.

The first gaskets and the second gasket are annular in shape, so that adjacent cascade channels are communicated.

Further, an angle of the end of tip of the arc starting pin is 30° to 45°.

Further, the cascade structure includes 5 to 11 cascade pieces.

Compared with the prior art, beneficial effects of the cascade arc plasma generator provided by the present disclosure are as follows:

The cascade arc plasma generator provided by the present disclosure includes the cathode structure, the cascade structure, and the anode structure sequentially connected along the plasma jet direction. When the cascade arc plasma generator works, working gas to be ionized enters the ionization chamber through the gas inlet channel. A potential difference exists between the plurality of the arc starting pins and the anode body, the plurality of the arc starting pins all break down the working gas, and the working gas is ionized to form a plasma. The plasma passes through the ionization chamber, the plasma channel, and the anode channel which are connected in sequence, so as to be jetted outside the cascade arc plasma generator and enter an external device, to interact with a material sample to be studied. The plurality of the arc starting pins are parallel to each other and arranged at intervals, the ends of tips thereof located in the same plane, and the plane is perpendicular to the plasma jet direction, so as to form a planar plasma source. The planar plasma source is able to irradiate a large-area material sample or a plurality of material samples at a time. And it is possible to be applied to different shapes of material samples by changing an arrangement of the plurality of the arc starting pins, which facilitates an improvement of an efficiency of the irradiation and accelerates a process of experiment and study.

### BRIEF DESCRIPTION OF THE DRAWINGS

FIG. 1 is a sectional schematic of a cascade arc plasma generator according to an embodiment of the present disclosure;

FIG. 2 is a partial sectional schematic of a three-dimensional structure of a cascade arc plasma generator according to an embodiment of the present disclosure;

FIG. 3 is an enlarged schematic of a region A in FIG. 1;

FIG. 4 is an enlarged schematic of a region B in FIG. 3.

In the figures: 100, cascade arc plasma generator; 1, cathode structure; 11, cathode assembly; 111, arc starting pin seat; 1111, first protrusion; 11111, first mounting groove; 1112, first mounting cavity; 112, arc starting pin; 12, cathode seat; 121, ionization chamber; 122, gas inlet channel; 123, second mounting groove; 1231, second mounting surface; 13, water-cooling assembly; 131, water-cooling box; 1311, cooling channel; 1312, water inlet channel; 1313, water outlet channel; 132, water inlet pipe; 133, water outlet pipe; 14, protection ring; 141, sleeving portion; 1411, sleeving channel; 1412, first annular rib; 14121, first mounting surface; 142, jet portion; 1421, jet channel; 15, gas inlet pipe; 2, cascade structure; 21, cascade piece; 211, cascade channel; 22, plasma channel; 23, first gasket; 24, second gasket; 3, anode structure; 31, anode body; 311, anode channel; 312, second connecting hole; 32, cooling pipe; 4, connecting structure; 41, flange; 42, connecting rod; 43, locking nut.

### DETAILED DESCRIPTION

Specific embodiments of the present disclosure are further described in detail below with reference to the accompanying drawings and examples. The following embodiments are used to illustrate the present disclosure, but are not intended to limit the scope of the present disclosure.

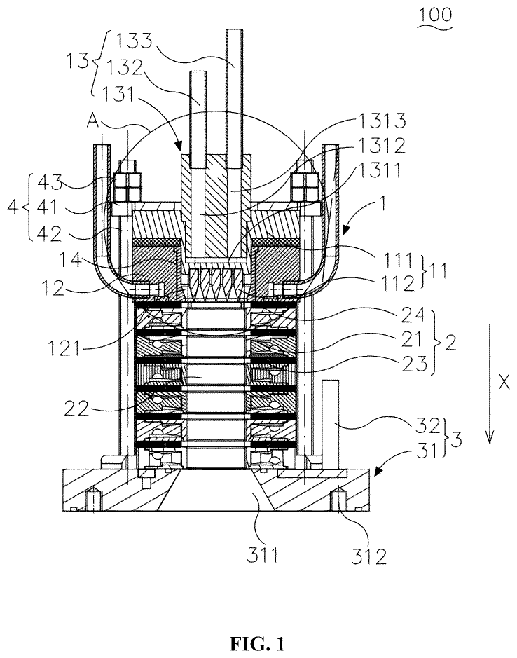

As shown in FIGS. 1 to 4, a cascade arc plasma generator 100 according to an embodiment of the present disclosure includes a cathode structure 1, a cascade structure 2, and an anode structure 3 sequentially connected along a plasma jet direction X; the cathode structure 1 includes a cathode assembly 11 and a cathode seat 12, and the cathode assembly 11 includes an arc starting pin seat 111 and a plurality of arc starting pins 112, and the plurality of the arc starting pins 112 are parallel to each other and are connected to one end of the arc starting pin seat 111; the cathode seat 12 is provided with an ionization chamber 121, and the ionization chamber 121 runs through the cathode seat 12 in the plasma jet direction X, the arc starting pin seat 111 is partially disposed in the ionization chamber 121 so that the plurality of the arc starting pins 112 are located in the ionization chamber 121, ends of tips of the plurality of the arc starting pins 112 are disposed towards the cascade structure 2, and the ends of the tips of the plurality of the arc starting pins 112 are located in a same plane, and the plane is perpendicular to the plasma jet direction X; the cathode seat 12 is further provided with a plurality of gas inlet channels 122, and the gas inlet channels 122 are configured to deliver gases into the ionization chamber 121.

The anode structure 3 includes an anode body 31, and the anode body 31 is provided with an anode channel 311 running through an upper surface and a lower surface thereof; the cascade structure 2 includes a plurality of cascade pieces 21, the plurality of the cascade pieces 21 are stacked along the plasma jet direction X and disposed between the cathode seat 12 and the anode body 31; each of the cascade pieces 21 is provided with a cascade channel 211, the cascade channel 211 runs through the cascade piece 21 in the plasma jet direction X, so that when the plurality of the cascade pieces 21 are stacked, a plurality of the cascade channels 211 are sequentially communicated to form a plasma channel 22; and the ionization chamber 121, the plasma channel 22 and the anode channel 311 are provided opposite to each other and sequentially communicated.

Based on the above, when the cascade arc plasma generator 100 works, working gas to be ionized enters the ionization chamber 121 through the gas inlet channel 122. A potential difference exists between the cathode assembly 11 and the anode body 31, and under an action of the arc starting pins 112, the working gas is electrically broken down, so that the working gas is ionized, thereby forming a plasma. As the plurality of the arc starting pins are parallel to each other and arranged at intervals, and the ends of the tips of the plurality of the arc starting pins 112 are located on the same plane, when the plurality of the arc starting pins 112 electrically break down the working gas, a planar plasma source is formed, which can irradiate a large-area material sample or irradiate a plurality of material samples at a time with a plasma of high beam intensity, and also can be applied to different shapes of material samples by changing an arrangement of the plurality of the arc starting pins. The high beam intensity is a beam intensity of more than or equal to 10²⁴m⁻²s⁻¹, and the large-area material sample is a material sample with a diameter of more than 10 mm. The plasma passes through the ionization chamber 121, the plasma channel 22, and the anode channel 311 in sequence, and is jetted out of the cascade arc plasma generator 100 to an external device where it interacts with a material sample.

Preferably, as shown in FIGS. 1 and 4, a maximum distance between two adjacent arc starting pins 112 is defined as D1, and a diameter of each of the arc starting pins 112 is defined as D2. In the present embodiment, 0.1×D2≤D1≤0.2×D2, and D1 should not be too large or too small. If D1 is too small, the two adjacent arc starting pins 112 are too close to each other and may be in contact with each other, resulting in only one point-shaped plasma source being formed, and if D1 is too large, the two adjacent the arc starting pins 112 are too far apart, resulting in the plurality of the arc starting pins finally forming a plurality of point-shaped plasma sources, thereby the planar plasma source cannot be smoothly formed.

Preferably, as shown in FIG. 1, in order to ensure an irradiation effect of the cascade arc plasma generator 100 and to reduce an interaction between the plasma and a material of the cascade piece, the ionization chamber 121, the plasma channel 22, and the anode channel 311 are coaxially arranged, and a diameter of the plasma channel 22 matches a diameter of the ionization chamber 121.

Preferably, the cathode structure 1 further includes a gas inlet pipe 15, the gas inlet pipe 15 is connected to the gas inlet channel 122 to facilitate communication between the gas inlet channel 122 and an external gas source, which facilitates the working gas entering the ionization chamber 121 through the gas inlet channel 122.

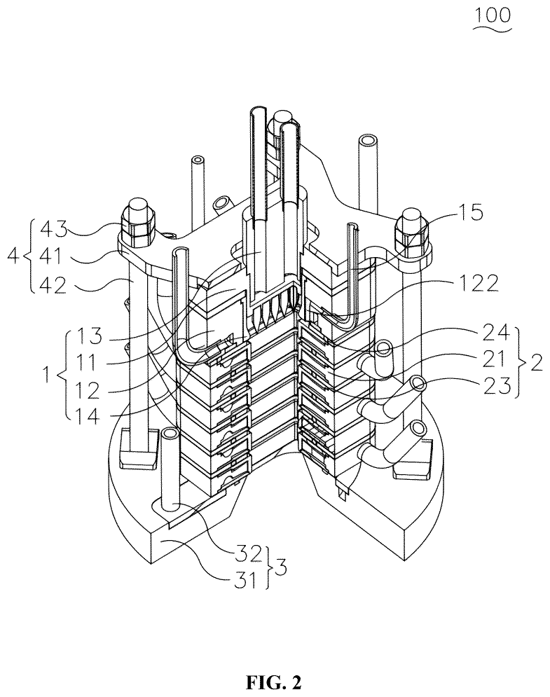

Further, as shown in FIGS. 1 and 2, in order to facilitate mounting of the arc starting pin seat 111 into the ionization chamber 121, the arc starting pin seat 111 is provided with a first protrusion 1111 at an end thereof towards the cascade structure 2, the first protrusion 1111 is embedded in the ionization chamber 121, and the arc starting pin 112 is provided on an end surface of the first protrusion 1111.

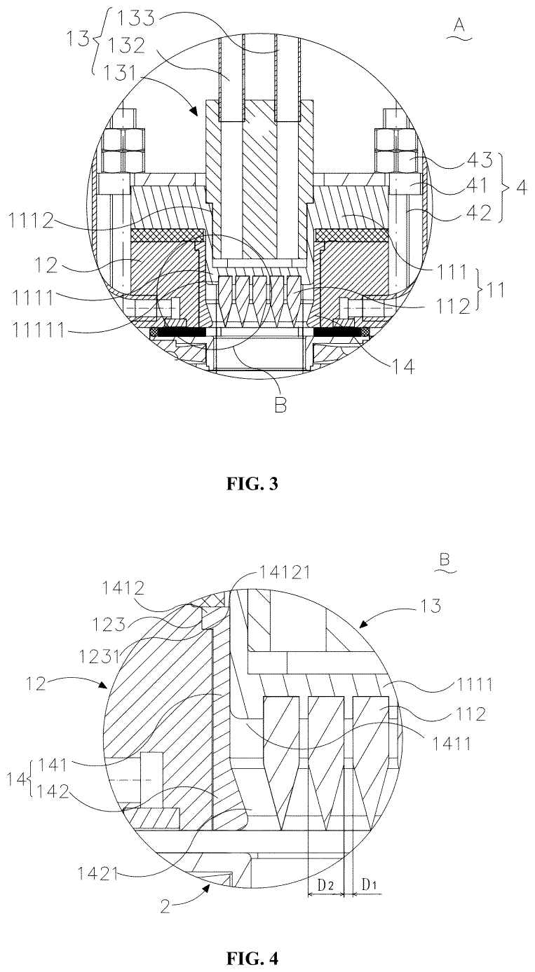

Preferably, as shown in FIGS. 1 and 3, in order to facilitate the mounting and positioning of the arc starting pin 112, a plurality of first mounting grooves 11111 for mounting the arc starting pins 112 are provided at an end of the first protrusion 1111. A number of the first mounting grooves 11111 in the present embodiment are the same as a number of the arc starting pins 112, so that each of the first mounting grooves 11111 is provided with the arc starting pin 112. However, in some other embodiments, the number and an arrangement of the first mounting grooves 11111 may be set in combination with a plurality of common arrangements, so that a planar plasma source adapted to the material sample may be formed by mounting the arc starting pins 112 in a part of the plurality of the first mounting grooves 11111 to improve an applicability of the arc starting pin seat 111.

Further, as shown in FIGS. 1 and 2, since the cathode assembly 11 heats up during a working process of the cascade arc plasma generator 100, the cathode assembly 11 is required to be cooled to ensure normal working thereof; therefore, the cathode structure 1 further includes a water-cooling assembly 13; a first mounting cavity 1112 is provided at one end, away from the arc starting pin 112, of the arc starting pin seat 111, and the water-cooling assembly 13 is hermetically connected to the first mounting cavity 1112.

Further, as shown in FIGS. 1 and 2, in order to realize a cooling of the cathode assembly 11 by the water-cooling assembly 13, the water-cooling assembly 13 includes a water-cooling box 131, a water inlet pipe 132, and a water outlet pipe 133; the water-cooling box 131 is hermetically connected to the first mounting cavity 1112, with a gap between a bottom surface of the water-cooling box 131 and a bottom surface of the first mounting cavity 1112, and a cooling channel 1311 is formed by an enclosure of an outer wall of the water cooling box 131 and a cavity wall of the first mounting cavity 1112; in this embodiment, the water-cooling box 131 is hermetically welded into the first mounting cavity 1112, so that the water-cooling box 131 and the arc starting pin seat 111 are fixedly connected to form a whole, and sealing can be achieved or a sealing effect can be further improved through welding while the connection is achieved, thereby preventing a coolant from leaking. The water-cooling box 131 is provided therein with a water inlet channel 1312 and a water outlet channel 1313, the water inlet channel 1312 and the water outlet channel 1313 both run through two side surfaces, in the plasma jet direction X, of the water-cooling box 131, and the water inlet channel 1312 and the water outlet channel 1313 are communicated with the cooling channel 1311 respectively; the water inlet pipe 132 is communicated with the water inlet channel 1312 and the water outlet pipe 133 is communicated with the outlet water passage 1313. An external coolant is accessed through the water inlet pipe 132, so that the coolant enters the cooling channel 1311 through the water inlet channel 1312 to cool the cathode assembly 11, and then passes through the water outlet channel 1313 and is discharged to the external device through the water outlet pipe 133.

Further, as shown in FIGS. 1 to 4, in order to protect the cathode seat 12 and reduce an interaction of plasma with the cathode seat 12, the cathode structure 1 further includes a protection ring 14, the protection ring 14 is disposed in the ionization chamber 121, and the protection ring 14 is hermetically connected to an inner side wall of the ionization chamber 121; in this embodiment, the protection ring 14 is hermetically welded to a cavity wall of the ionization chamber 121 to avoid a movement of the protection ring 14, so as to ensure a protecting effect of the protection ring 14 on the cathode seat 12; the protection ring 14 includes a sleeving portion 141 and a jet portion 142 sequentially disposed along the plasma jet direction X, the sleeving portion 141 is provided with a sleeving channel 1411, the jet portion 142 is provided with a jet channel 1421, and the sleeving channel 1411 is communicated with the jet channel 1421; the sleeving portion 141 sleeves outside the first protrusion 1111, an inner surface of the sleeving portion 141 is tightly attached to an outer surface of the first protrusion 1111, and an outer surface of the sleeving portion 141 is tightly attached to the cavity wall of the ionization chamber 121 to protect the cathode seat 12; the jet portion 142 is provided outside the ends of the tips of the plurality of the arc starting pins 112, a gap exists between an inner surface of the jet portion 142 and each of the arc starting pins 112, an outer surface of the jet portion 142 is tightly attached to the cavity wall of the ionization chamber 121, and a diameter of the jet channel 1421 gradually decreases along the plasma jet direction to form a shape similar to that of a nozzle, so as to facilitate a jetting of the plasma.

Preferably, as shown in FIGS. 1 to 4, in order to facilitate mounting and positioning of the protection ring 14, a first annular rib 1412 is annularly provided around a periphery of one end, away from the arc starting pin 112, of the sleeving portion 141. The first annular rib 1412 includes a first mounting surface 14121 facing the cascade structure 2, and a second mounting groove 123 is correspondingly annularly provided around one end, away from the cascade structure 2, of the cathode seat 12; the first annular rib 1412 is clamped into the second mounting groove 123, and the second mounting groove 123 includes a second mounting surface 1231 opposite to the first mounting surface 14121, and when the protection ring 14 is mounted to the ionization chamber 121, the second mounting surface 1231 is tightly attached to the first mounting surface 14121 to ensure that the protection ring 14 is welded to a set position, thereby protecting the ionization chamber 121.

Further, as shown in FIGS. 1 and 2, the cascade arc plasma generator 100 further includes a connecting structure 4, the connecting structure 4 includes a flange 41, a plurality of connecting rods 42, and a plurality of groups of locking nuts 43, and a number of the groups of the locking nuts 43 is the same as a number of the connecting rods 42; the flange 41 covers and is provided above the end, away from the arc starting pin 112, of the arc starting pin seat 111, and the flange 41 is further provided with first connecting holes with a number thereof same as the connecting rods 42, and each of the connecting rods 42 is provided along the plasma jet direction, one end of which is fixedly arranged on the anode body 31, and an other end of which passes through one of the first connecting holes and is fixedly connected with one group of the locking nuts 43, in order to make the cathode structure 1, the cascade structure 2, and the anode structure 3 connected and combined as a whole, which is beneficial to guaranteeing air tightness of the plasma channel; the connecting rods 42 are made of an insulating material, so that the cathode structure 1 and the anode structure 3 are insulated.

Preferably, as shown in FIG. 2, in order to prevent the flange 41 from interfering with the water-cooling box 131, which would result in the flange 41 not being able to cover and be provided above the end, away from the arc starting pin 112, of the arc starting pin seat 111, the flange 41 is provided with a connecting channel. The connecting channel runs through the flange 41 in the plasma jet direction X, so that the flange 41 sleeves on a periphery of the water-cooling box 131 and covers and is provided above the end, away from the arc starting pin 112, of the arc starting pin seat 111.

Further, as shown in FIGS. 1 and 2, in order to make the plasma channel 22 form a gas-tight channel, the cascade structure 2 further includes a plurality of first gaskets 23 and a second gasket 24, and each of the first gaskets 23 is provided between two adjacent cascade pieces 21; the second gasket 24 is provided between the cathode seat 12 and an uppermost cascade piece 21 of the cascade structure 2; and the first gaskets 23 and the second gasket 24 are annular in shape to allow adjacent cascade channels 211 to be communicated.

Further, as shown in FIG. 1, an angle of the end of the tip of each of the arc starting pins 112 is 30° to 45°. If the angle of the end of the tip of the arc starting pin 112 is too large, it will be difficult to achieve that the tip of the arc starting pin discharges and starts an arc so as to form the plasma, and if the angle of the end of the tip of the arc starting pin 112 is too small, the tip of the arc starting pin will be easily ablated in a short time so as to fail to start an arc and discharge, and a cost of using and maintaining is increased. The arc starting pins 112 in this embodiment are made of pure tungsten.

Preferably, as shown in FIGS. 1 and 3, in a orthographic projection along a radial direction of the arc starting pin 112, an inner wall of the jet channel 1421 and an inclined surface of the tip of the arc starting pin 112 are parallel to each other, so that the jet channel 1421 is arranged corresponding to the tip of the arc starting pin 112, which is beneficial to improving a jetting efficiency of the plasma.

Further, as shown in FIG. 1, the cascade structure includes 5 to 11 cascade slices, and a production cost of the cascade arc plasma generator 100 is controlled while sufficient plasma concentration is guaranteed.

Preferably, as shown in FIG. 1, in order to facilitate a connection of the cascade arc plasma generator 100 with the external device, a plurality of second connecting holes 312 are provided at a bottom end of the anode body 31.

Preferably, as shown in FIGS. 1 and 2, in addition to the cathode assembly 11 needing to be cooled, the anode body 31 also needs to be cooled, and the anode structure 3 includes a cooling pipe 32, and a cooling passage is provided in the anode body 31, and the cooling pipe 32 is connected to the cooling passage.

Preferably, as shown in FIG. 1, since the plasma will have a tendency of diffusion after it is formed and jetted, in order to reduce an influence of the plasma on the anode body 31 so as to prolong a service life of the anode body 31, a diameter of the anode channel 311 gradually increases from top to bottom to form a flared shape, thereby reducing an interaction of the plasma with a material of an inner wall of the anode channel 311, and thereby reducing sputtering the material into a plasma beam.

A working process of the present disclosure is as follows: the working gas to be ionized enters the ionization chamber 121 from the gas inlet channel 122, the potential difference exists between the cathode assembly 11 and the anode body 31, and under the action of the plurality of the arc starting pins 112 disposed in parallel and at intervals, the working gas is electrically broken down, and the working gas is ionized to produce the plasma, and the plurality of the arc starting pins 112 act together to form a planar plasma source with a certain area so as to be distinguished from a single-point or multi-point plasma source; the plasma, under an action of the potential difference, departs from the ionization chamber 121, passes through the plasma channel 22 and the anode channel 311 in turn, and is jetted out from the cascade arc plasma generator 100, reaches a vacuum chamber in the external device, and interacts with a material sample in the vacuum chamber.

In summary, embodiments of the present disclosure provide the cascade arc plasma generator, which electrically breaks down the working gas under the action of the arc starting pins 112 to ionize the working gas to form the plasma, the plurality of the arc starting pins 112 are parallel to each other and arranged at intervals, and act simultaneously to break down the working gas, and as the ends of tips of the plurality of the arc starting pins 112 are all located in the same plane to form the planar plasma source, the plasma is formed in the ionization chamber 121 and jetted out from the cascade arc plasma generator 100 through the plasma channel 22 and the anode channel 311 in turn, and enters the external device and then interacts with the material sample; by means of the planar plasma source formed by the plurality of the arc starting pins 112 being parallel to each other and arranged at intervals, it is possible to break through a limitation of small irradiation area of the existing cascade arc plasma generator, and it is possible to irradiate a large-area material sample or irradiate a plurality of material samples at a time, thus improving an efficiency, and thus accelerating a process of experiment and study.

The above are only preferred embodiments of the present disclosure, and it should be noted that, for a person of ordinary skill in the art, several improvements and replacements may be made without departing from the technical principle of the present disclosure, and the improvements and replacements should also fall within the protection scope of the present disclosure.

1. A cascade arc plasma generator, comprising a cathode structure, a cascade structure, and an anode structure sequentially connected along a plasma jet direction;
wherein the cathode structure comprises a cathode assembly and a cathode seat, the cathode assembly comprises an arc starting pin seat and a plurality of arc starting pins, and the plurality of the arc starting pins are parallel to each other and are connected to one end of the arc starting pin seat at intervals; the cathode seat is provided with an ionization chamber, the ionization chamber runs through the cathode seat in the plasma jet direction, and the arc starting pin seat is partially disposed in the ionization chamber, thereby the plurality of the arc starting pins are located in the ionization chamber, and ends of tips of the plurality of the arc starting pins are disposed towards the cascade structure, and the ends of the tips of the plurality of the arc starting pins are located in a same plane, and the plane is perpendicular to the plasma jet direction; and
the cathode seat is further provided with a plurality of gas inlet channels configured to deliver gases into the ionization chamber;
the anode structure comprises an anode body, the anode body is provided with an anode channel running through an upper surface and a lower surface thereof; and
the cascade structure comprises a plurality of cascade pieces, the plurality of the cascade pieces are sequentially stacked along the plasma jet direction and disposed between the cathode seat and the anode body; each of the cascade pieces is provided with a cascade channel, the cascade channel runs through the cascade piece in the plasma jet direction, thereby when the plurality of the cascade pieces are stacked, a plurality of the cascade channels are sequentially communicated to form a plasma channel; and the ionization chamber, the plasma channel, and the anode channel are provided opposite to each other and sequentially communicated.

2. The cascade arc plasma generator according to claim 1, wherein an end, facing the cascade structure, of the arc starting pin seat is provided with a first protrusion, the first protrusion is embedded in the ionization chamber, and the arc starting pins are provided on an end surface of the first protrusion.

3. The cascade arc plasma generator according to claim 1, wherein the cathode structure further comprises a water-cooling assembly; and
a first mounting cavity is provided at an end, away from the arc starting pins, of the arc starting pin seat, and the water-cooling assembly is hermetically connected to the first mounting cavity.

4. The cascade arc plasma generator according to claim 3, wherein the water-cooling assembly comprises a water-cooling box, a water inlet pipe, and a water outlet pipe;
the water-cooling box is hermetically connected to the first mounting cavity, a gap is formed between a bottom surface of the water-cooling box and a bottom surface of the first mounting cavity, and a cooling channel is formed by an enclosure of an outer wall of the water-cooling box and a cavity wall of the first mounting cavity, and the water-cooling box is provided therein with a water inlet channel and a water outlet channel, the water inlet channel and the water outlet channel run through two side surfaces, which are in the plasma jet direction, of the water-cooling box, and the water inlet channel and the water outlet channel are communicated with the cooling channel respectively; and
the water inlet pipe is communication with the water inlet channel, and the water outlet pipe is communication with the water outlet channel.

5. The cascade arc plasma generator according to claim 2, wherein the cathode structure further comprises a protection ring disposed in the ionization chamber, the protection ring is hermetically connected to an inner side wall of the ionization chamber; the protection ring comprises a sleeving portion and a jet portion sequentially disposed along the plasma jet direction, provided with a sleeving channel, the jet portion is provided with a jet channel, and the sleeving channel is communicated with the jet channel;
the sleeving portion sleeves outside the first protrusion, an inner surface of the sleeving portion is attached to an outer surface of the first protrusion, and an outer surface of the sleeving portion is attached to a cavity wall of the ionization chamber; and
the jet portion is provided outside the ends of the tips of the plurality of the arc starting pins, a gap exists between an inner surface of the jet portion and each of the arc starting pins, and an outer surface of the jet portion is attached to the cavity wall of the ionization chamber, and a diameter of the jet channel gradually decreases from top to bottom.

6. The cascade arc plasma generator according to claim 1, further comprising a connecting structure, wherein the connecting structure comprises a flange, a plurality of connecting rods, and a plurality of groups of locking nuts, and a number of the groups of the locking nuts is the same as a number of the connecting rods; and
the flange is provided above the end, away from the arc starting pins, of the arc starting pin seat, the flange is further provided with first connecting holes with a number thereof same as the connecting rods, each of the connecting rods is arranged along the plasma jet direction, and is provided with one end fixedly arranged on the anode body, and an other end passing through one of the first connecting holes and fixedly connected with one group of the locking nuts, and the connecting rods are made of insulating materials.

7. The cascade arc plasma generator according to claim 1, wherein the cascade structure further comprises a plurality of first gaskets and a second gasket, each of the plurality of first gaskets is provided between two adjacent cascade pieces;
the second gasket is provided between the cathode seat and an uppermost cascade piece of the cascade structure; and
the first gaskets and the second gasket are annular in shape to communicate adjacent cascade channels.

8. The cascade arc plasma generator according to claim 1, wherein an angle of the end of the tip of each of the arc starting pins is 30° to 45°.

9. The cascade arc plasma generator according to claim 1, wherein a number of the cascade pieces of the cascade structure is from 5 to 11.
